(19) United States
(12) Patent Application Publication
(10) Pub. No.: US 2026/0322058 A1
(43) Pub. Date: Oct. 15, 2026

(54) OPTICAL AMPLIFIER AND APPARATUS THEREFOR

(71) Applicants: ASML Netherlands B.V., Veldhoven (NL); Trumpf Lasersystems for Semiconductor Manufacturing SE, Ditzingen (DE)

(72) Inventors: Toni Wil Mathijs JANSSEN, Weert (NL); Alexander Matthijs STRUYCKEN, Eindhoven (NL); Robert Gabriël Maria LANSBERGEN, Schiedam (NL); Mark GESCHWANDNER, Korntal-Münchingen (DE); Petrus Antonius Johannes VAN MELICK, Weert (NL)

(73) Assignees: ASML Netherlands B.V., Veldhoven (NL); Trumpf Lasersystems for Semiconductor Manufacturing SE, Ditzingen (DE)

(21) Appl. No.: 19/483,914

(22) PCT Filed: Apr. 11, 2024
(86) PCT No.: PCT/EP2024/059903

§ 371 Date: Nov. 12, 2025

(30) Foreign Application Priority Data
May 22, 2023 (EP) 23174432.7

(51) Int. Cl. H01S 3/036; G03F 7/00; G03F 7/20; H01S 3/038

(52) U.S. Cl. CPC H01S 3/036; G03F 7/2004; G03F 7/70033; H01S 3/0387

(57) ABSTRACT

An apparatus for an optical amplifier configured to amplify a laser beam comprises: an amplification chamber; a swirl inducer; and a pair of electrodes. The amplification chamber is generally of the form of a tube. The swirl inducer is arranged to induce swirl in a fluid when pumped through the amplification chamber so as to induce a generally helical flow of fluid through the amplification chamber. The pair of electrodes is arranged to apply a voltage within the amplification chamber. Each of the pair of electrodes is generally helical. The swirl inducer and the pair of electrodes are configured such that a pitch of the generally helical flow of fluid through the amplification chamber is generally matched to a pitch of the pair of electrodes along the amplification chamber.

### CROSS-REFERENCE TO RELATED APPLICATIONS

This application claims priority of EP application 23174432.7 which was filed on 22 May 2023 and which is incorporated herein in its entirety by reference.

### FIELD

The present invention relates to an apparatus that may form a component of an optical amplifier configured to amplify a laser beam. The present invention also relates to an optical amplifier comprising such an apparatus. The optical amplifier may form part of an amplification system for a laser system. The laser system may comprise a carbon dioxide (CO₂) laser, which may form part of a laser produced plasma (LPP) radiation source. In turn, the LPP radiation source may form part of a lithographic system, i.e., provide radiation to a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

One known type of EUV radiation source is a laser produced plasma (LPP) source in which tin droplets are irradiated by laser pulses so as to form a tin plasma which emits EUV radiation. The laser pulses are typically high power in order to generate the tin plasma. In order to achieve the desired power, the laser pulses are typically amplified in an amplification system that comprises a plurality of optical amplifiers (for example single-pass amplifiers arranged in series).

It may be desirable to provide alternative or improved optical amplifiers, and components therefor, that may at least partially address one or more problems in known arrangements, whether identified herein or otherwise.

### SUMMARY

According to a first aspect of the present disclosure there is provided an apparatus for an optical amplifier configured to amplify a laser beam, the apparatus comprising: an amplification chamber, the amplification chamber being generally of the form of a tube; a swirl inducer arranged to induce swirl in a fluid when pumped through the amplification chamber so as to induce a generally helical flow of fluid through the amplification chamber; and a pair of electrodes arranged to apply a voltage within the amplification chamber, wherein each of the pair of electrodes is generally helical; wherein the swirl inducer and the pair of electrodes are configured such that a pitch of the generally helical flow of fluid through the amplification chamber is generally matched to a pitch of the pair of electrodes along the amplification chamber.

The apparatus according to the first aspect may be considered to form a subsystem or component of an optical amplifier.

The optical amplifier may form part of a carbon dioxide (CO₂) laser. In use, a pump is configured to pump a gain medium around a gain medium system comprising the amplifier chamber. The gain medium may comprise a mixture of gases. For example, the gain medium may comprise a mixture of any combination of the following: carbon dioxide, helium and/or nitrogen. As the gain medium is pumped through the amplifier chamber, the swirl inducer causes the gain medium to follow a helical flow through the amplification chamber.

The apparatus for an optical amplifier according to the first aspect is advantageous, as now discussed.

In use, the amplifier chamber may be configured to receive the laser beam at an inlet and output an amplified laser beam from an outlet. It is desirable to minimize any pointing error induced by the optical amplifier. For example, it may be desirable for the amplified laser beam to be well aligned with (and at a negligible angle to) an optical axis of the optical amplifier. In order to ensure that the amplified laser beam is well aligned with the optical axis of the optical amplifier, an alignment process may be performed. Such an alignment process may comprise directing an alignment laser beam into an inlet of the optical amplifier, allowing the alignment laser beam to propagate through the optical amplifier and then measuring a position of the alignment laser beam at an outlet of the optical amplifier. The optical amplifier may comprise one or more movable or adjustable optical elements (for example rotatable mirrors) that can be adjusted until the position of the alignment laser beam at the output of the optical amplifier coincides with a nominal or desired position. For safety reasons, such alignment processes are typically performed when the optical amplifier is not operating and, therefore, the gain medium is not under the same conditions as when the optical amplifier is operating. For example, a temperature and a pressure of the gain medium may be less during an alignment process than they would be during operation of the optical amplifier. That is, during the alignment process the gain medium gas may be relatively cool and at relatively low pressure whereas in use (during operation of the optical amplifier) the gain medium gas may be at significantly higher temperatures and pressures.

In some existing optical amplifiers having generally tubular amplification chambers the electrodes are provided on an exterior of the amplification chambers. With such an arrangement, it is known to introduce some turbulence in the flow of a gain medium through the amplification chamber. This turbulence can increase a density of gain medium near the wall(s) of the amplification chamber, where the electrodes are, thus increasing an amplification of the radiation achieved within the amplification chamber (for example relative to an arrangement wherein there is a laminar flow of gain medium through the amplification chamber).

The inventors of the present invention have realized that the refractive index within the amplification chamber is dependent upon both the temperature and pressure within the amplification chamber. The inventors have further realized that there will, in general, be significant temperature and pressure gradients within the amplification chamber (particularly when the optical amplifier is first switched on and the gain medium is heating up), which, in turn, will result in refractive index gradients. The inventors have further realized that if there is a gradient of refractive index that has a radial component (due to temperature and pressure gradients in the amplification chamber) these will result in pointing errors. The inventors have further realized that such effects are enhanced or exaggerated when the optical amplifier is switched on, as the temperature of the gain medium increases from a starting temperature up to a steady-state operating temperature, during a time period that may be referred to as a start-up period. The inventors have further realized that during the start-up period (which could be on a time scale of less than 30 ms) the pointing errors can be so significant that the position of the laser beam can “jump” during the start-up period by a significant, and sometimes unacceptable, amount. This is partly due to the small thermal mass of the gain medium, which can mean that the change in temperature at start-up of the optical amplifier can be very sudden.

An axis of the amplification chamber may extend through a center of the, generally tubular, amplification chamber. Any reference to an axial direction will be understood to be a direction that is parallel to this axis. Any reference to a radial direction will be understood to be a direction that is perpendicular to, and which passes through, this axis.

As stated above, in some known arrangements some swirl is introduced to the flow of gas through an amplification chamber. However, in some such known arrangements the swirl is induced by apparatus that is upstream of the amplification chamber. Such an arrangement results in a variable amount of swirl along the amplification chamber, with maximum swirl immediately after the apparatus that induces that swirl. After a sufficiently long distance through a tube the gas flow would exhibit laminar flow. If the swirl induced is generally helical, a pitch of that helix will vary (increase) along the length of the amplification chamber. Therefore, if the electrodes are helical and have a constant or uniform pitch then, with such an arrangement, the pitch of the generally helical flow of fluid through the amplification chamber (which is not constant) will not be matched to a pitch of the pair of electrodes along the amplification chamber (which is constant).

The inventors of the present invention have realized that if a swirl of the gas flow through the amplification chamber is matched to the shape of the electrodes along a length of the amplification chamber, then pointing errors caused by the changes in temperature and pressure during start-up of the optical amplifier (that the apparatus forms part of) will be minimized. This may be achieved in various ways. In general, this may be achieved by: (a) electrodes having a variable pitch; and/or (b) a swirl inducer that is at least partially disposed in the amplification chamber, as now discussed. In general, the better the matching of the swirl of the gas flow through the amplification chamber to the shape of the electrodes along a length of the amplification chamber, the smaller the pointing errors caused by the changes in temperature and pressure during start-up of the optical amplifier will be.

Each of the pair of electrodes may be generally helical, having a pitch that increases from a first end of the amplification chamber to a second end of the amplification chamber.

In use, the fluid may enter the amplification chamber at the first end and flow to the second end. With such an arrangement, if, in use, the swirl inducer is upstream of the amplification chamber then the (turbulent) helical flow of fluid through the amplification chamber (the pitch of which will also be increasing from the first end to the second end) can be matched to the pitch of the pair of electrodes along the amplification chamber.

According to a second aspect of the present disclosure there is provided an apparatus for an optical amplifier configured to amplify a laser beam, the apparatus comprising: an amplification chamber, the amplification chamber being generally of the form of a tube; a swirl inducer arranged to induce swirl in a fluid when pumped through the amplification chamber so as to induce a generally helical flow of fluid through the amplification chamber; and a pair of electrodes arranged to apply a voltage within the amplification chamber, wherein each of the pair of electrodes is generally helical, having a pitch that increases from a first end of the amplification chamber to a second end of the amplification chamber.

Advantageously, the apparatus according to the second aspect of the present invention allows for the swirl inducer and the pair of electrodes to be configured such that a pitch of the generally helical flow of fluid through the amplification chamber is generally matched to a pitch of the pair of electrodes along the amplification chamber. In particular, the apparatus according to the second aspect allows for such matching even for arrangements wherein the swirl induced by the swirl inducer decreases from the first end of the amplification chamber to the second end of the amplification chamber; for example when the swirl inducer is disposed outside of (and, for example, upstream of) the amplification chamber.

The swirl inducer may be axially adjacent the first end of the amplification chamber.

In use, the fluid may enter the amplification chamber at the first end and flow to the second end. With such an arrangement, the swirl inducer may be considered to be upstream of the amplification chamber (axially adjacent the first end thereof). For such embodiments, it may be that there is no significant axial overlap between the swirl inducer and the amplification chamber.

The swirl inducer may be at least partially disposed in the amplification chamber.

For example, the swirl inducer may axially overlap with the amplification chamber. With such an arrangement, it may be possible to achieve a flow of fluid that is generally helical, and which has a reasonably constant pitch. With such an arrangement, the helical flow of fluid through the amplification chamber may be matched to the pitch of the pair of electrodes that also have generally constant pitch along the amplification chamber.

According to a third aspect of the present disclosure there is provided an apparatus for an optical amplifier configured to amplify a laser beam, the apparatus comprising: an amplification chamber, the amplification chamber being generally of the form of a tube; a swirl inducer arranged to induce swirl in a fluid when pumped through the amplification chamber so as to induce a generally helical flow of fluid through the amplification chamber, wherein the swirl inducer is at least partially disposed in the amplification chamber; and a pair of electrodes arranged to apply a voltage within the amplification chamber, wherein each of the pair of electrodes is generally helical.

Advantageously, the apparatus according to the third aspect of the present invention allows for the swirl inducer and the pair of electrodes to be configured such that a pitch of the generally helical flow of fluid through the amplification chamber is generally matched to a pitch of the pair of electrodes along the amplification chamber. In particular, the apparatus according to the third aspect allows for such matching even for arrangements a pitch of the generally helical electrodes is constant or uniform.

The swirl inducer and the pair of electrodes may be configured such that a chirality of the generally helical flow of fluid through the amplification chamber is the same as a chirality of the pair of electrodes along the amplification chamber.

It will be appreciated that the chirality (also referred to as handedness) of a helix is the sense in which the helix rotates or twists about its axis as viewed along that axis. Put differently, if the generally helical flow of fluid through the amplification chamber and the pair of electrodes where both viewed in the axial direction, they would both twist about the axis in the same sense (either both clockwise or both anti-clockwise).

The amplification chamber may be formed from a material that is substantially “transparent” to an applied voltage (for example a radio frequency voltage). That is, the amplification chamber may be formed from a suitable material that allows the pair of electrodes to be disposed outside the amplification chamber whilst still being operable to apply a voltage within the amplification chamber.

The amplification chamber may be formed from quartz.

That is, the amplification chamber may comprise a quartz tube. Advantageously, quartz is substantially “transparent” to an applied RF voltage. Therefore, such embodiments allow the pair of electrodes to be disposed outside the amplification chamber whilst still being operable to apply a voltage within the amplification chamber.

The pair of electrodes may be not disposed in an interior of the amplification chamber.

For example, the pair of electrodes may be arranged on an exterior of a wall of the amplification chamber. Alternatively, the pair of electrodes may be at least partially embedded in a wall of the amplification chamber.

The pair of electrodes may be arranged to apply a voltage within the amplification chamber that is generally transverse or perpendicular to an axis of the amplification chamber.

The swirl inducer may comprise a generally tubular body and a screw structure disposed within the generally tubular body.

The swirl inducer may comprise a generally tubular body and plurality of baffles disposed within the generally tubular body, wherein each of the plurality of baffles extends generally radially and axially within the generally tubular body, and wherein each of the plurality of baffles is twisted such that a radial direction of the baffle varies along an axial extent of the baffle.

According to a fourth aspect of the present disclosure there is provided an optical amplifier configured to amplify a laser beam, the optical amplifier comprising: an apparatus according to any one of the first, second or third aspects of the present disclosure, wherein the amplification chamber is configured to receive the laser beam at an inlet and output an amplified laser beam from an outlet; and a first pump configured to pump a gain medium around a gain medium system comprising the swirl inducer and the amplification chamber.

It will be appreciated that the amplifier chamber of an optical amplifier is typically not a resonant cavity (in contrast to the main lasing chamber of a laser). Optical amplifiers may, for example, be single-pass systems in which a laser beam only passes through the amplifier chamber once.

The optical amplifier according to the fourth aspect is advantageous, as now discussed.

The optical amplifier may comprise an apparatus according to the first aspect of the present disclosure such that a swirl of the (gain medium) gas flowing through the amplification chamber is matched to the shape of the electrodes along a length of the amplification chamber. The optical amplifier may comprise an apparatus according to the second or third aspects of the present disclosure, which enables such matching. Advantageously, as discussed above, with such optical amplifiers pointing errors caused by the changes in temperature and pressure during start-up of the optical amplifier will be minimized. The start-up period may be on a time scale of less than 100 ms. The start-up period may be on a time scale of less than 30 ms. The start-up period may be on a time scale of the order of 30 ms.

The optical amplifier of the fourth aspect of the present disclosure may comprise a plurality of apparatus according to any one of the first, second or third aspects of the present disclosure, each amplification chamber being configured to receive the laser beam at an inlet and output an amplified laser beam from an outlet and wherein the first pump is configured to pump the gain medium around a gain medium system comprising the swirl inducers and the amplification chambers of the plurality of apparatus.

For example, in one embodiment the optical amplifier may comprise sixteen of the apparatus according to any one of the first, second or third aspects of the present disclosure.

In some embodiments, an optical path of each apparatus according to any one of the first, second or third aspects of the present disclosure may be of the order of 0.5 m. In some embodiments, an optical path of the optical amplifier may be of the order of 8 m. In such embodiments it may be desirable for an offset from the optical axis caused during start-up to be less than 0.04 mm. Over an optical path length of 8 m, an offset from the optical axis of 0.04 mm corresponds to an angular pointing error of 5 μrad.

The swirl inducer and the pair of electrodes may be configured such that a matching of the pitch of the generally helical flow of fluid through the amplification chamber to a pitch of the pair of electrodes along the amplification chamber is such that an angular pointing error that results during a start-up period in which a temperature of the gain medium increases from a starting temperature up to a steady-state operating temperature the is less than 10 prad.

In some embodiments, the swirl inducer and the pair of electrodes may be configured such that a matching of the pitch of the generally helical flow of fluid through the amplification chamber to a pitch of the pair of electrodes along the amplification chamber is such that an angular pointing error that results during a start-up period in which a temperature of the gain medium increases from a starting temperature up to a steady-state operating temperature the is less than 5 prad.

The optical amplifier may further comprise one or more heat exchangers, which form part of the gain medium system, and which are arranged to transfer heat from the gain medium in the gain medium system to a cooling fluid in a cooling system (for example after the gain medium has passed through the amplification chamber).

The optical amplifier may further comprise a second pump configured to pump a cooling fluid through the one or more heat exchangers so as to exchange heat with the gain medium.

According to a fifth aspect of the present disclosure there is provided a method of designing an apparatus for an optical amplifier, the optical amplifier comprising: an amplification chamber, the amplification chamber being generally of the form of a tube and configured to receive the laser beam at an inlet and output an amplified laser beam from an outlet; a swirl inducer arranged to induce swirl in a fluid when pumped through the amplification chamber so as to induce a generally helical flow of fluid through the amplification chamber; a pair of electrodes arranged to apply a voltage within the amplification chamber, wherein each of the pair of electrodes is generally helical; and a first pump configured to pump a gain medium around a gain medium system comprising the amplification chamber; and wherein the method comprises: matching the swirl inducer to the pair of electrodes such that a pitch of the generally helical flow of fluid through the amplification chamber is generally matched to a pitch of the pair of electrodes along the amplification chamber.

Advantageously, the method according to the fifth aspect of the present disclosure allows for the apparatus according to the first, second or third aspects of the present disclosure and/or the optical amplifier according to the fourth aspect to be designed.

According to a sixth aspect of the present disclosure there is provided an amplification system for use in a laser system, the system comprising: a plurality of optical amplifiers, at least one or each optical amplifier of the plurality of optical amplifier comprising an optical amplifier according to the fourth aspect of the present disclosure.

According to a seventh aspect of the present disclosure there is provided a laser system comprising: a laser configured to generate a laser beam; and the amplification system according to the sixth aspect of the present disclosure wherein the amplification system is configured to amplify the laser beam.

According to an eighth aspect of the present disclosure there is provided a radiation system comprising: an EUV radiation source; and a laser system according to the seventh aspect of the present disclosure.

According to a ninth aspect of the present disclosure there is provided a lithographic system comprising a radiation system according to the eighth aspect of the present disclosure and a lithographic apparatus.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 depicts an exemplary amplification system for use in a laser system of the radiation system of FIG. 1;

FIG. 3 is a schematic of a first example optical amplifier according to an embodiment of the present disclosure;

FIG. 4A shows an example embodiment of an amplification chamber and a swirl inducer that may form part of the optical amplifier shown in FIG. 3;

FIG. 4B shows the amplification chamber shown in FIG. 4A;

FIG. 5A shows a first contour map of the refractive index in an amplification chamber as a function of both a longitudinal direction (i.e. a nominal direction in which the laser beam propagates) and a transverse direction (i.e. a direction perpendicular to a nominal propagation direction of the laser beam), a ray of the laser beam is shown as a dashed arrow;

FIG. 5B shows a second contour map of the refractive index in an amplification chamber as a function of both a longitudinal direction (i.e. a nominal direction in which the laser beam propagates) and a transverse direction (i.e. a direction perpendicular to a nominal propagation direction of the laser beam), a ray of the laser beam is shown as a dashed arrow;

FIG. 6 is a schematic of a second example optical amplifier according to an embodiment of the present disclosure, which is a variant of the optical amplifier shown in FIG. 3;

FIG. 7 is a schematic illustration of a first embodiment of a swirl inducer disposed upstream of an amplifier chamber, which may form part of the optical amplifier of FIG. 3 or FIG. 6;

FIG. 8 is a schematic illustration of a second embodiment of a swirl inducer disposed upstream of an amplifier chamber, which may form part of the optical amplifier of FIG. 3 or FIG. 6;

FIG. 9 is a perspective view of an example optical amplifier according to an embodiment of the present disclosure;

FIG. 10 illustrates an optical path defined by the optical amplifier shown in FIG. 9;

FIG. 11A illustrates gas flow paths within the optical amplifier shown in FIG. 9 along which a gain medium flows as part of a gain medium system; and

FIG. 11B is an exploded view of the gas flow paths within the optical amplifier shown in FIG. 9, separated into a first part of the gain medium system and a second part of the gain medium system.

### DETAILED DESCRIPTION

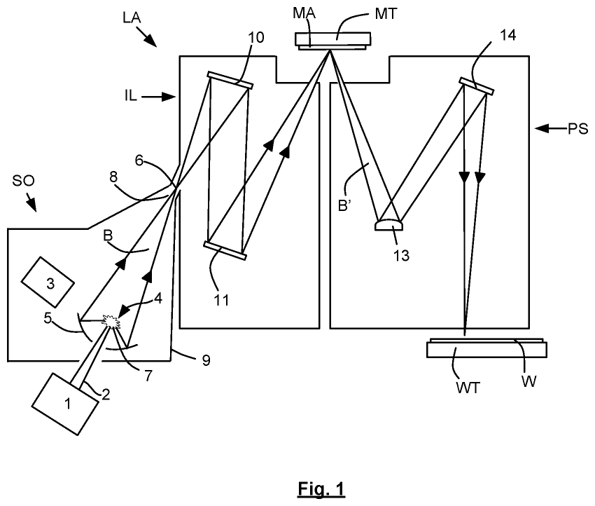

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

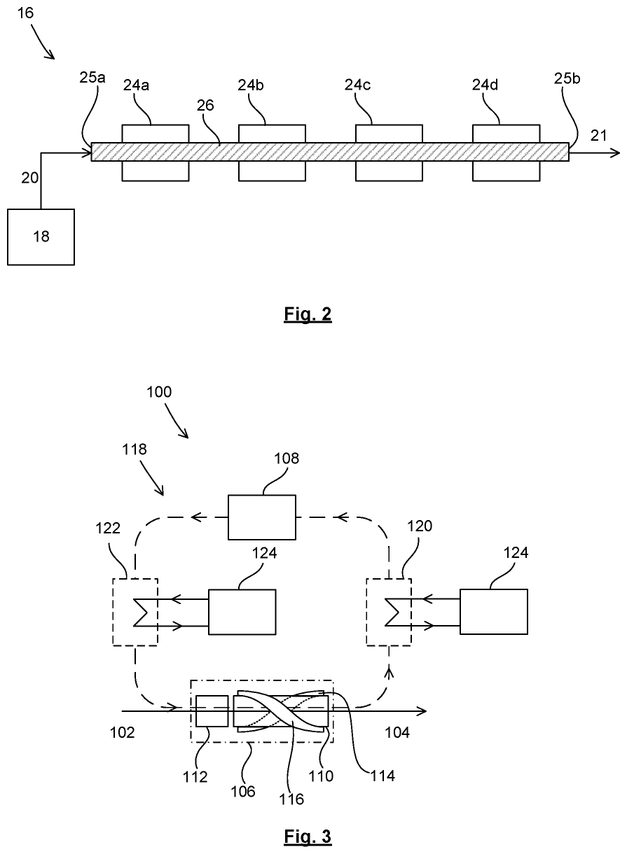

FIG. 2 shows an exemplary amplification system 16 for use in the laser system 1 of the radiation source SO shown in FIG. 1. The amplification system 16 may also be referred to as an optical amplification system. The laser system 1 may comprise a laser 18, such as the CO₂ laser. The laser 18 may be configured to generate a laser beam 20. The laser 18 may be referred to as a seed laser 18 and the laser beam 20 may be referred to as a seed laser beam 20. The laser beam 20 may comprise a plurality of pulses. The laser system 1 may comprise one or more optical elements, such as one or more mirrors, beam expanders, lenses and/or other elements (not shown), for directing the laser beam into the amplification system 16.

The amplification system 16 comprises a plurality of optical amplifiers 24a-24d, four of which are shown in FIG. 2. However, it will be appreciated that in other embodiments, the system may comprise more or fewer than four optical amplifiers. In general, the amplification system 16 comprises at least one optical amplifier. Each of the optical amplifiers 24a-24d is configured to amplify the laser beam 20 so as to produce an output laser beam 21. The output laser beam 21 may form the laser beam 2 shown in FIG. 1 and which is incident upon the tin at the plasma formation region 4.

The amplification system 16 comprises an optical system 26. The optical system 26 may also be referred to as a relay optical system. The optical system 26 is configured to optically couple or connect at least one of the optical amplifiers 24a-24d to at least one other of the optical amplifiers 24a-24d. In the present embodiment, the optical system 26 is configured to optically couple or connect the amplifiers 24a-24d in series to each other. For example, the optical system 26 may be configured to optically couple or connect the optical amplifiers 24a-24d to each other so that the laser beam 20 is directed from a first amplifier 24a to a second amplifier 24b, from the second amplifier 24b to a third amplifier 24c and from the third amplifier 24c to a fourth amplifier 24d. The optical system 26 may comprise a plurality of optical elements, such as a plurality of mirrors, lenses, telescopes and/or the like. The optical amplifiers 24a-24d may be arranged to sequentially amplify the laser beam 20.

The amplification system 16 may comprise an input 25a, e.g. at which the laser beam 20 enters the amplification system 16. The amplification system 16 may comprise an output 25b, e.g. at which the amplified laser beam 21 exits the amplification system 16. At the input 25a of the amplification system 16, the laser beam may have a power between about 100 W and 200 W, such as about 140 W. At the output 25b of the amplification system 16, the amplified laser beam 21 may have a power between about 25 kW and 50 kW.

Some embodiments of the present invention relate to an optical amplifier, as now discussed. An example optical amplifier 100 according to an embodiment of the present disclosure is shown schematically in FIG. 3. The optical amplifier 100 may form part of the laser system 1 shown in FIG. 1 and/or the amplification system 16 shown in FIG. 2. For example, any or all of the optical amplifiers 24a-24d shown in FIG. 2 may comprise the optical amplifier 100 shown in FIG. 3.

The optical amplifier 100 is configured to amplify a laser beam. That is, the optical amplifier 100 is arranged to receive an input laser beam 102 and output an amplified laser beam 104. The optical amplifier comprises: an apparatus 106 according to an embodiment of the present disclosure; and a first pump 108.

The apparatus 106 may be considered to form a subsystem or component of an optical amplifier 100. The apparatus 106 comprises: an amplification chamber 110, a swirl inducer 112 and a pair of electrodes 114, 116.

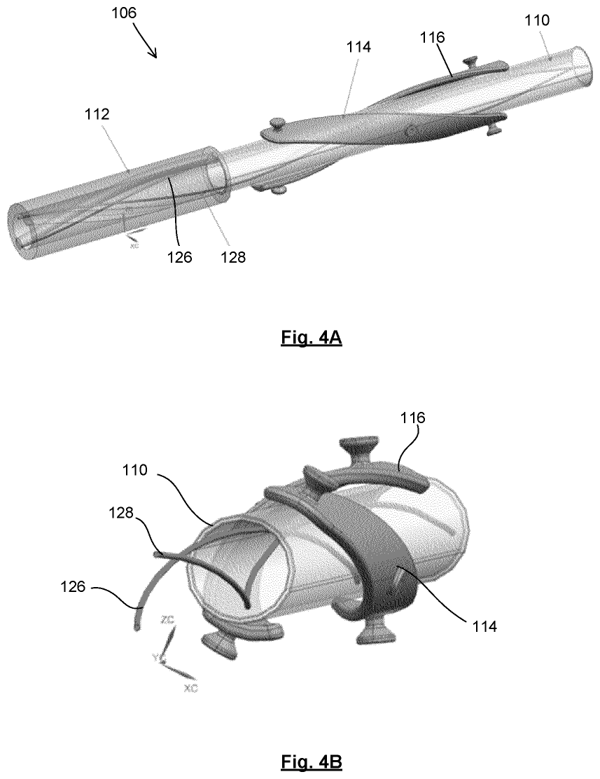

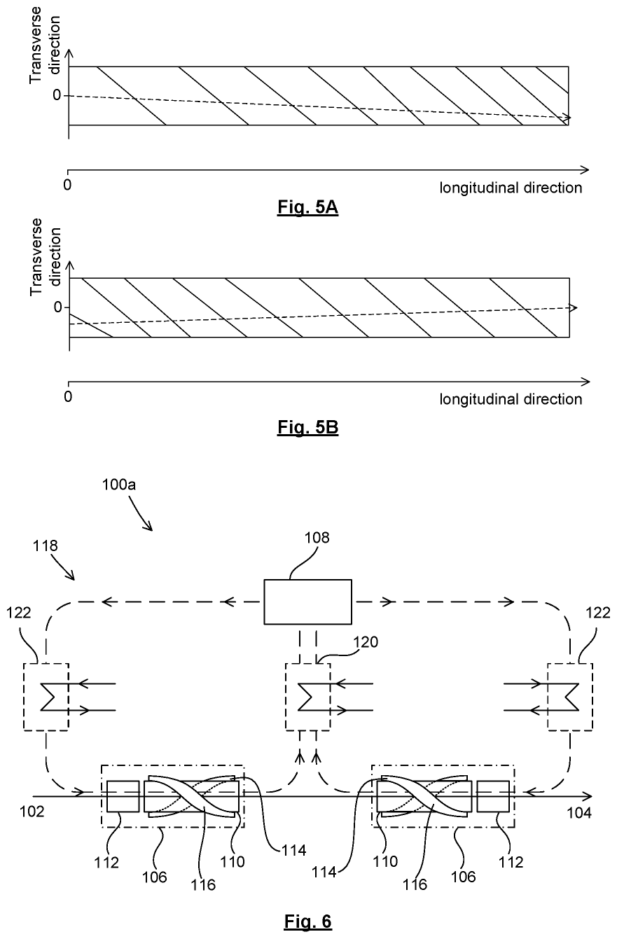

The amplification chamber 110 is generally of the form of a tube (as will be described more fully below with reference to FIGS. 4A and 4B, which show an example embodiment of the amplification chamber 110 and the swirl inducer 112). The amplification chamber 110 may alternatively be referred to as a laser chamber.

The swirl inducer 112 is arranged to induce swirl in a fluid when pumped through the amplification chamber 110 so as to induce a generally helical flow of fluid through the amplification chamber 110.

The pair of electrodes 114, 116 is arranged to apply a voltage within the amplification chamber 110. As will be described more fully below (with reference to FIGS. 4A and 4B) each of the pair of electrodes 114, 116 is generally helical. It will be appreciated by the skilled person that the apparatus 106 may further comprise a power supply operable to apply a voltage across the two electrodes 114, 116 although these features are omitted in this schematic representation of the optical amplifier 100 for ease of understanding.

The amplification chamber 110 is configured to receive the laser beam 102 at an inlet and output the amplified laser beam 104 from an outlet.

The first pump 108 is configured to pump a gain medium around a gain medium system 118 comprising the amplification chamber 110 and the swirl inducer 112 of the apparatus 106. The gain medium system 118 of the optical amplifier 100 comprises: the first pump 108; the apparatus 106; and, optionally, one or more heat exchangers 120, 122. The gain medium system 116 of the optical amplifier 100 is a closed loop system. The optical amplifier 100 may form part of a carbon dioxide (CO₂) laser. The gain medium may comprise a mixture of gases. For example, the gain medium may comprise a mixture of any combination of the following: carbon dioxide, helium and/or nitrogen.

Optionally, as shown in FIG. 3, a first heat exchanger 120 (which forms part of the gain medium system 118) may be arranged to transfer heat from the gain medium in the gain medium system 118 to a cooling fluid in a cooling system 124 after the gain medium has passed through the amplification chamber 110. The first heat exchanger 120 may be referred to as a gas cooler.

Optionally, as shown in FIG. 3, the gain medium system 118 of the optical amplifier 100 may further comprise a second heat exchanger 122 arranged to transfer heat from the gain medium in the gain medium system 118 to a cooling fluid in the cooling system 124 after the gain medium has passed through the first pump 108 and before it has entered the amplification chamber 110. The second heat exchanger 122 may either form part of the same cooling system 124 as the first heat exchanger 110. Alternatively, the second heat exchanger 122 may form part of a separate cooling system to that of the first heat exchanger 120.

The cooling system 124 may comprise a second pump (not shown) configured to pump a cooling fluid through the heat exchangers 120, 122 so as to exchange heat with the gain medium. Optionally, the cooling system 124 of the optical amplifier 100 may be a closed loop system and may further comprise a heat sink (not shown) which is arranged to transfer heat away from the cooling fluid in the cooling system 124. For example, the cooling system may be a two-phase system and the heat sink may comprise a condenser. Optionally, the cooling system 124 of the optical amplifier 100 may further comprise a reservoir or tank (not shown) containing cooling fluid. The cooling fluid may comprise a liquid and/or a gas. The cooling fluid may comprise water.

Optionally, the optical amplifier 100 may comprise a catalyst (not shown) in part of the gain medium system 118 and disposed such that as the gain medium is pumped around a gain medium system 118 by the first pump 108 at least a portion of the gain medium is adjacent to, or in contact with, the catalyst. The catalyst may comprise any suitable material such as, for example, gold and/or platinum.

The swirl inducer 112 and the pair of electrodes 114, 116 are configured such that a pitch of the generally helical flow of fluid through the amplification chamber 110 is generally matched to a pitch of the pair of electrodes 114, 116 along the amplification chamber. In order to promote a better understanding of this matching of the pitches of the generally helical flow of fluid through the amplification chamber 110 and the pair of electrodes 114, 116, the definition of the pitch of a helix is now discussed.

A helical shape may be defined using the following parametric equations:

$$x = r cos ( t + ∅ ) \qquad ( 1 )$$

$$y = r sin ( t + ∅ ) \qquad ( 2 )$$

$$z = α \cdot t \qquad ( 3 )$$

where r is a radius of the helix, is t a parameter that describes a position along the helix, ∅ is a phase of the helix, and α is a pitch parameter. For a regular helix, the pitch parameter α is constant and the axial separation between two points on the helix that are separated by one full turn of the helix is 2πα. For a regular helix, the axial separation between two points on the helix that are separated by one full turn of the helix may be referred to as the pitch of the helix. As used herein, the pitch of helix is intended to mean, more generally, the pitch parameter α of the helix. Note that this more general definition means that a pitch can be defined for a helical shape that does not extend over more than one turn. This is of particular relevance since, as can be appreciated from FIGS. 4A and 4B, in some embodiments the shape of the electrodes 114, 116 is such that neither one completes a full turn of the helix.

The optical amplifier 100 may form part of a carbon dioxide (CO₂) laser. In use, the first pump 108 is configured to pump a gain medium around the gain medium system 118 comprising the swirl inducer 112 and the amplifier chamber 110. The gain medium may comprise a mixture of gases. For example, the gain medium may comprise a mixture of any combination of the following: carbon dioxide, helium and/or nitrogen. As the gain medium is pumped through the amplifier chamber 110, the swirl inducer 112 causes the gain medium to follow a helical flow through the amplification chamber 110. In particular, as shown in FIGS. 4A and 4B the swirl inducer 112 may be arranged to causes the gain medium to follow two generally helical flow paths 126, 128.

The apparatus 106 which may be considered to form a subsystem or component of the optical amplifier 100 (and the optical amplifier 100 comprising the apparatus 106) are advantageous, as now discussed.

In use, the amplifier chamber 110 receives the laser beam 102 at the inlet and outputs the amplified laser beam 104 from the outlet. It is desirable to minimize any pointing error induced by the optical amplifier 100. For example, it may be desirable for the amplified laser beam 104 to be well aligned with (and at a negligible angle to) an optical axis of the optical amplifier 100. In order to ensure that the amplified laser beam 104 is well aligned with the optical axis of the optical amplifier 100, an alignment process may be performed. Such an alignment process may comprise directing an alignment laser beam into an inlet of the optical amplifier 100, allowing the alignment laser beam to propagate through the optical amplifier 100 and then measuring a position of the alignment laser beam at an outlet of the optical amplifier 100. The optical amplifier 100 may comprise one or more movable or adjustable optical elements (for example rotatable mirrors) that can be adjusted until the position of the alignment laser beam at the output of the optical amplifier coincides with a nominal or desired position. For safety reasons, such alignment processes are typically performed when the optical amplifier 100 is not operating and, therefore, the gain medium is not under the same conditions as when the optical amplifier 100 is operating. For example, a temperature and a pressure of the gain medium may be less during an alignment process than they would be during operation of the optical amplifier 100. That is, during the alignment process the gain medium gas may be relatively cool and at relatively low pressure whereas in use (during operation of the optical amplifier 100) the gain medium gas may be at significantly higher temperatures and pressures.

In some existing optical amplifiers having generally tubular amplification chambers the electrodes are provided on an exterior of the amplification chambers. With such an arrangement, it is known to introduce some turbulence in the flow of a gain medium through the amplification chamber. This turbulence can increase a density of gain medium near the wall(s) of the amplification chamber, where the electrodes are, thus increasing an amplification of the radiation achieved within the amplification chamber (for example relative to an arrangement wherein there is laminar flow of the gain medium through the amplification chamber).

The inventors of the present invention have realized that the refractive index within the amplification chamber is dependent upon both the temperature and pressure within the amplification chamber 110. The inventors have further realized that there will, in general, be significant temperature and pressure gradients within the amplification chamber 110 (particularly when the optical amplifier 100 is first switched on and the gain medium is heating up), which, in turn, will result in refractive index gradients.

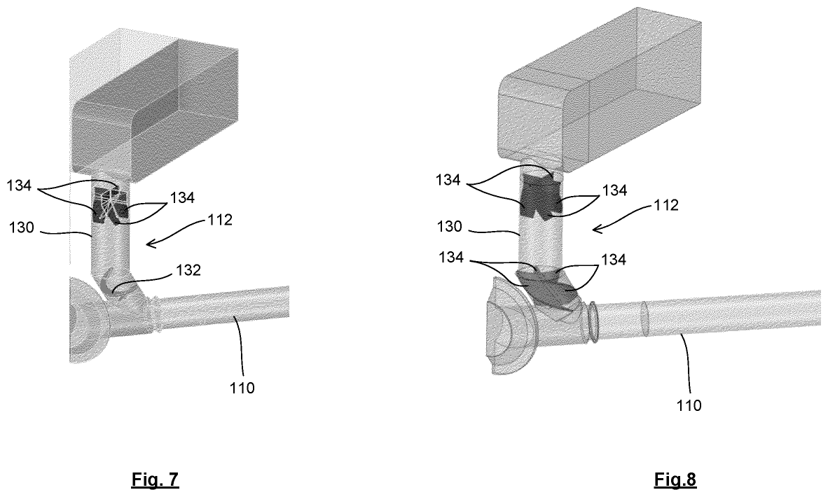

The inventors have further realized that if there is a gradient of refractive index that has a radial component (due to temperature and pressure gradients in the amplification chamber) these will result in pointing errors. This is illustrated schematically in FIGS. 5A and 5B, which each show a contour map of the refractive index in the amplification chamber as a function of both a longitudinal direction (i.e. a nominal direction in which the laser beams 102, 104 propagate) and a transverse direction (i.e. a direction perpendicular to a nominal propagation direction of the laser beams 102, 104). In both cases, there is a gradient of refractive index that has a radial component (i.e. the contour lines are not all aligned with the transverse direction): in FIG. 5A the refractive index is increasing towards the top right of the Figure and in FIG. 5B the refractive index is increasing towards the bottom left of the Figure. A ray of the laser beam is shown as a dashed arrow. In FIG. 5A, the gradient of refractive index is such that a laser beam that initial is centered in the transverse direction is refracted downwards in the Figure, resulting in a pointing error. As shown in FIG. 5B, when the gradient of refractive index is reversed, a laser beam that is initially off-center can be refracted upwards in the Figure so as to cancel this pointing error.

The inventors have further realized that such effects are enhanced or exaggerated when the optical amplifier 100 is switched on, as the temperature of the gain medium increases from a starting temperature up to a steady-state operating temperature, during a time period that may be referred to as a start-up period. The inventors have further realized that during the start-up period (which could be on a time scale of less than 30 ms) the pointing errors can be so significant that the position of the laser beam can “jump” during the start-up period by a significant, and sometimes unacceptable, amount. This is partly due to the small thermal mass of the gain medium, which can mean that the change in temperature at start-up of the optical amplifier can be very sudden.

An axis of the amplification chamber 110 may extend through a center of the, generally tubular, amplification chamber 110. Any reference to an axial direction will be understood to be a direction that is parallel to this axis. Any reference to a radial direction will be understood to be a direction that is perpendicular to, and which passes through, this axis.

As stated above, in some known arrangements some swirl is introduced to the flow of gas through an amplification chamber. However, in some such known arrangements the swirl is induced by apparatus that is upstream of the amplification chamber. Such an arrangement results in a variable amount of swirl along the amplification chamber, with maximum swirl immediately after the apparatus that induces that swirl. After a sufficiently long distance through a tube the gas flow would exhibit laminar flow. If the swirl induced is generally helical, a pitch of that helix will vary (increase) along the length of the amplification chamber. Therefore, if the electrodes are helical and have a constant or uniform pitch then, with such an arrangement, the pitch of the generally helical flow of fluid through the amplification chamber (which is not constant) will not be matched to a pitch of the pair of electrodes along the amplification chamber (which is constant).

The inventors of the present invention have realized that if a swirl of the gas flow through the amplification chamber 110 is matched to the shape of the electrodes 114, 116 along a length of the amplification chamber 110 then pointing errors caused by the changes in temperature and pressure during start-up of the optical amplifier 100 (that the apparatus 106 forms part of) will be minimized. This may be achieved in various ways. In general, this may be achieved by: (a) electrodes 114, 116 having a variable pitch; and/or (b) a swirl inducer 112 that is at least partially disposed in the amplification chamber 110, as discussed below. In general, the better the matching of the swirl of the gas flow through the amplification chamber 110 to the shape of the electrodes 114, 116 along a length of the amplification chamber 110, the smaller the pointing errors caused by the changes in temperature and pressure during start-up of the optical amplifier 100 will be.

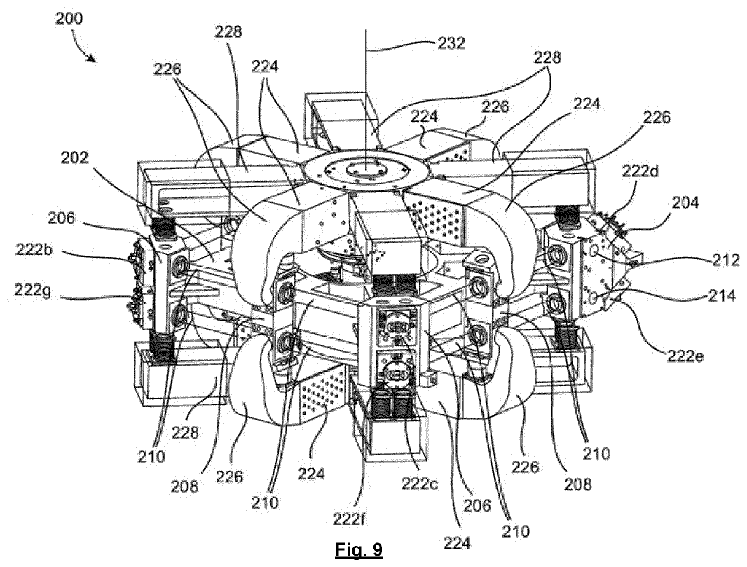

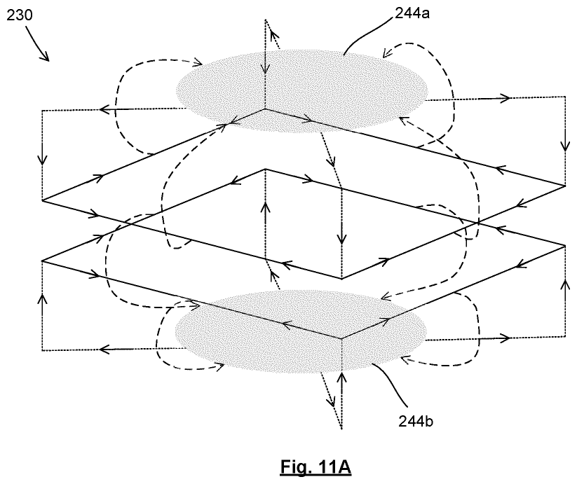

As will be described further below (with reference to FIGS. 9 to 11B), in some embodiments, the optical amplifier 100 may comprise a plurality of apparatus 106 of the type described above and comprising an amplification chamber 110 and a swirl inducer 112. The amplification chamber 110 of each such apparatus 106 is configured to receive the laser beam at an inlet and output an amplified laser beam from an outlet. The first pump 108 is configured to pump the gain medium around a gain medium system comprising the plurality of apparatus 106 of the type described above and comprising an amplification chamber 110 and a swirl inducer 112. FIG. 6 shows an example optical amplifier 100a according to an embodiment of the present disclosure that is generally of the form of the optical amplifier 100 shown schematically in FIG. 3 but having two apparatus 106 (each having an amplifier chamber 110 and a swirl inducer 112). For clarity and ease of understanding the cooling system 124 is not shown in detail in FIG. 6 although it will be understood that it may have any of the features described above in relation to FIG. 3. In this example, the radiation beam output from the outlet of an amplification chamber 110 of a first apparatus 106 is received by the inlet of an amplification chamber 110 of a second apparatus 106. In this example, the two amplification chambers 110 share a common first pump 108 and a common first heat exchanger 120. It will be appreciated that, in an alternative arrangement, the two amplification chambers 110 may alternatively share a common first pump 108 and a common second heat exchanger 122.

In some embodiments, each of the pair of electrodes 114, 116 is generally helical and has a pitch that increases from a first end of the amplification chamber 110 to a second end of the amplification chamber 110. In use, the fluid (gain medium) may enter the amplification chamber 110 at the first end and flow to the second end. With such an arrangement, if, in use, the swirl inducer 112 is upstream of the amplification chamber 110 then the helical flow of fluid through the amplification chamber 110 (the pitch of which will also be increasing from the first end to the second end) can be matched to the pitch of the pair of electrodes 114, 116 along the amplification chamber 110.

It will be appreciated that, as explained above, the electrodes 114, 116 need not complete a full turn of the helix and here pitch is to be interpreted as the pitch parameter α (cf. equation (3)).

Advantageously, embodiments wherein each of the pair of electrodes 114, 116 is generally helical and has a pitch that increases from a first end of the amplification chamber 110 to a second end of the amplification chamber 110 allows for the swirl inducer 112 and the pair of electrodes 114, 116 to be configured such that a pitch of the generally helical flow of fluid 126, 128 through the amplification chamber 110 is generally matched to a pitch of the pair of electrodes 114, 116 along the amplification chamber 110. In particular, it allows for such matching even for arrangements wherein the swirl induced by the swirl inducer 112 decreases from the first end of the amplification chamber 110 to the second end of the amplification chamber 110; for example, when the swirl inducer 112 is disposed outside of (and, for example, upstream of) the amplification chamber 110.

In some embodiments (see, for example, FIGS. 4A and 4B), the swirl inducer 112 is axially adjacent the first end of the amplification chamber 110. In use, the fluid may enter the amplification chamber 110 at the first end and flow to the second end. With such an arrangement, the swirl inducer 112 may be considered to be upstream of the amplification chamber 110 (axially adjacent the first end thereof). For such embodiments, it may be that there is no significant axial overlap between the swirl inducer 112 and the amplification chamber 110.

Alternatively, in some embodiments the swirl inducer 112 is at least partially disposed in the amplification chamber 110. For example, the swirl inducer 112 may axially overlap with the amplification chamber 110. For example, the apparatus that is acting on the fluid to induce the swirl may be, at least partially, disposed in the amplification chamber 110. With such an arrangement, it may be possible to achieve a flow of fluid 126, 128 that is generally helical, and which has a reasonably constant pitch. With such an arrangement, the helical flow of fluid 126, 128 through the amplification chamber 110 may be matched to the pitch of the pair of electrodes 114, 116 that also have generally constant pitch along the amplification chamber 110.

In some embodiments, the swirl inducer 112 and the pair of electrodes 114, 116 may be configured such that a chirality of the generally helical flow 126, 128 of fluid through the amplification chamber 110 is the same as a chirality of the pair of electrodes 114, 116 along the amplification chamber 110.

It will be appreciated that the chirality (also referred to as handedness) of a helix is the sense in which the helix rotates or twists about its axis as viewed along that axis. Put differently, if the generally helical flow of fluid 126, 128 through the amplification chamber 110 and the pair of electrodes 114, 116 where both viewed in the axial direction, they would both twist about the axis in the same sense (either both clockwise or both anti-clockwise).

In some embodiments, the amplification chamber 110 may be formed from quartz. That is, the amplification chamber 110 may comprise a quartz tube.

In some embodiments, the pair of electrodes 114, 116 are not disposed in an interior of the amplification chamber 110. For example, the pair of electrodes 114, 116 may be arranged on an exterior of a wall of the amplification chamber 110. Alternatively, the pair of electrodes may be at least partially embedded in a wall of the amplification chamber 110.

In some embodiments, the pair of electrodes 114, 116 are arranged to apply a voltage within the amplification chamber 110 that is generally transverse or perpendicular to an axis of the amplification chamber 110.

In some embodiments (see FIG. 7), the swirl inducer 112 may comprise a generally tubular body 130 and a screw structure 132 disposed within the generally tubular body 130.

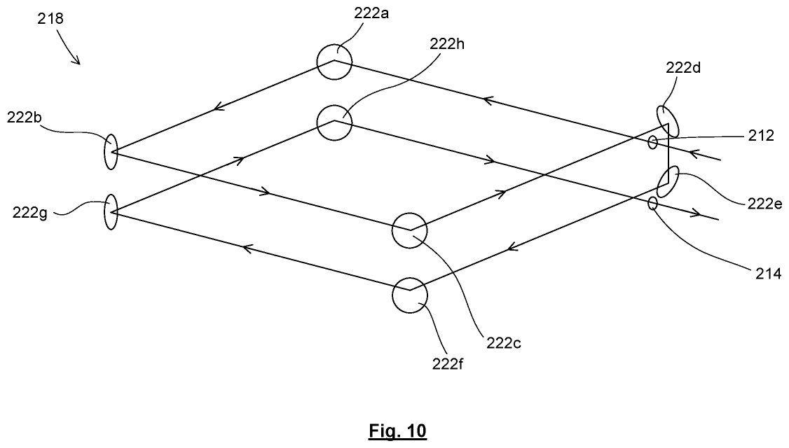

In some embodiments (see FIGS. 7 and 8), the swirl inducer 112 may comprise: a generally tubular body 130 and plurality of baffles 134 disposed within the generally tubular body 130. Each of the plurality of baffles 134 may extend generally radially and axially within the generally tubular body 130, and each of the plurality of baffles 134 may be twisted such that a radial direction of the baffle 134 varies along an axial extent of the baffle 134.

A specific example of an optical amplifier 200 that is an embodiment of an optical amplifier of the type shown schematically in FIGS. 3 and 6, and described above, is now described with reference to FIGS. 9 to 11B.

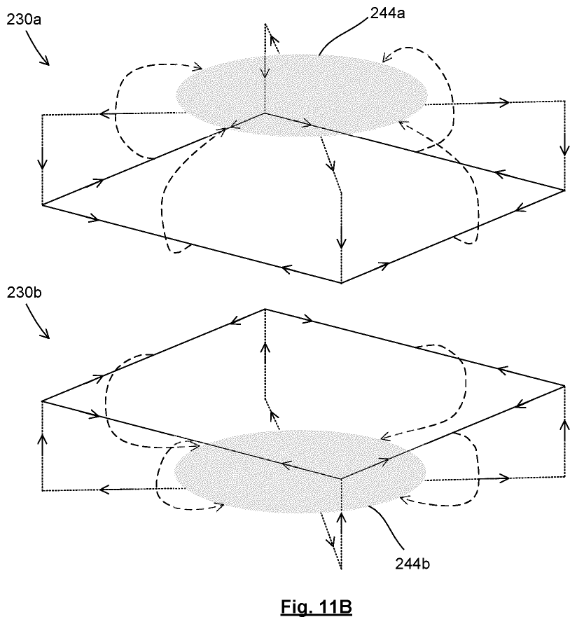

FIG. 9 shows the optical amplifier 200. FIG. 10 illustrates an optical path defined by the optical amplifier 200 shown in FIG. 9. FIGS. 11A and 11B illustrate gas flow paths within the optical amplifier 200 shown in FIG. 9 along which a gain medium flows as part of a gain medium system.

The optical amplifier 200 comprises: a central support body 202, an optical interface module 204, three corner modules 206, four side modules 208 and sixteen tubes 210. The central support body 202 comprises a generally square frame.

The optical interface module 204, the three corner modules 206 and the four side modules 208 are connected to, and supported by, the central support body 202. In particular, the optical interface module 204 and the three corner modules 206 are each provided at a different corner of the generally square frame of the central support body 202. The four side modules 208 are each provided at a different side of the generally square frame of the central support body 202, either between two corner modules 206 or between a corner module 206 and the optical interface module 204.

Two of the tubes 210 extend between each side module 208 and each of the two modules (either a corner module 206 or the optical interface module 204) at the two corners adjacent that side module 208. Each of the tubes 210 extends in a direction that is generally parallel to a side of the generally square frame of the central support body 202. Each of the tubes 210 may be formed from quartz.

Each of the tubes 210 may be considered to be an amplification chamber and may be generally equivalent to the amplification chamber 110 shown in FIGS. 3 and 6. Each of the tubes 210 is configured to receive a laser beam 102 at an inlet (one end of the tube 210) and output the amplified laser beam 104 from an outlet (a second end of the tube 210).

It will be appreciated that the optical amplifier 200 further comprises at least one pair of electrodes and a power supply operable to apply a voltage across the at least one pair of electrodes and within the tubes 210 although these features are omitted from the optical amplifier 200 shown in FIG. 9 for ease of understanding. In practice a pair of electrodes may be provided on an exterior of each of the tubes 210. One or more radiofrequency (RF) signals may be used to excite the molecules of gas mixture. The one or more radiofrequency signals may comprise one or more radiofrequency pulses. Alternatively, the one or more radiofrequency signals may comprise a continuous wave radiofrequency signal. The one or more radiofrequency signals may be applied to the gas mixture to create a population inversion of the molecules of the gas mixture. This may result in amplification of the laser beam passing through the gas mixture.

The pairs of electrodes are all generally helical, as described above with reference to FIGS. 3, 4A and 4B. Furthermore, it will be appreciated that a swirl inducer (not shown for ease of understanding FIG. 9) is provided for each of the amplification chambers (tubes) 210 so as to induce swirl in the fluid when pumped through the amplification chamber 210 so as to induce a generally helical flow of fluid through the amplification chamber 210. The swirl inducers and the pairs of electrodes are matched so that a pitch of the generally helical is matched to a pitch of the generally helical electrodes, as explained above with reference to FIGS. 3, 4A and 4B.

The tubes 210 form part of a closed loop gain medium system that is arranged to provide a flow of gas through each of the tubes 210 during use. This flow of gas through the tubes 210 will be described further below with reference to FIGS. 11A and 11B.

The optical interface module 204 defines an optical inlet 212 and an optical outlet 214. Each of the optical inlet 212 and optical outlet 214 comprises an aperture in a body of the optical interface module 204. In use, an input laser beam 216 (see FIG. 11) may be directed into the optical inlet 212. Said input laser beam 216 may then propagate into a first one of the tubes 210. In particular, the input laser beam 216 propagates along an optical path 218 defined by the optical amplifier 200 through each of the tubes 210 in sequence and then out of the optical outlet 214 as an amplified laser beam 220.

Although not shown in FIG. 9, each of the optical inlet 212 and optical outlet 214 comprises a window through which the laser beams 216, 220 can propagate while maintaining a working medium (gas mixture) within the tubes 210.

The optical amplifier 200 further comprises a plurality of optical elements 222a-222h, which define the optical path 218. The optical elements 222a-222h are reflective elements or mirrors. The optical elements 222a-222h are configured to direct the input laser beam 216 through a gas mixture in the tubes 210 along the optical path 218. The optical elements 222a-222h are supported by the optical interface module 204 and the three corner modules 206. In particular, each of the optical interface module 204 and the three corner modules 206 supports two optical elements 222a-222h. The optical path 218 comprises a first portion and second portion. The first portion of the optical path 218 is defined by three optical elements 222a-222c, one from each of the three corner modules 206. The first portion of the optical path 218 is generally square, with the laser beam propagating one way around the generally square frame of the central support 202. Similarly, the second portion of the optical path 218 is defined by three optical elements 222f-222h, one from each of the three corner modules 206 and is generally square. The second portion of the optical path 218 is generally square, with the laser beam propagating an opposite way around the generally square frame of the central support 202 to the first portion of the optical path 218. The two optical elements 222d-222e supported by the optical interface module 204 are configured to direct the laser beam from the first portion of the optical path 218 to the second portion of the optical path 218.

As mentioned above, the tubes 210 form part of a closed loop gain medium system that is arranged to provide a flow of gas through each of the tubes 210 during use. This closed loop gain medium system is now described with reference to FIGS. 9 and 11.

The optical amplifier 200 further comprises: at least one first pump (which is not visible in FIG. 9); eight first heat exchangers 224; eight return modules 226; and eight second heat exchangers 228.

The first pump may be generally equivalent to the first pump 108 in FIGS. 3 and 6, and is configured to pump a gain medium around a gain medium system 230 that comprises: the second heat exchangers 228, the sixteen tubes 210, the eight return modules 226 and the eight first heat exchangers 224. The gain medium system 230 may be generally equivalent to the gain medium system 118 of the optical amplifier 100 shown in FIG. 3. The gain medium system 230 is a closed loop system. The optical amplifier 200 may form part of a carbon dioxide (CO₂) laser. The gain medium may comprise a mixture of gases. For example, the gain medium may comprise a mixture of any combination of the following: carbon dioxide, helium and/or nitrogen.

FIG. 11A illustrates gas flow paths within the optical amplifier 200 shown in FIG. 9 along which a gain medium flows as part of a gain medium system 230. An axis of the optical amplifier 200 is shown in FIG. 6. In the following description of the flow paths of the gain medium system 230 any reference to an axial direction will be understood to be a direction that is parallel to the axis 232. Similarly, any reference to a radial direction will be understood to be a direction that is perpendicular to, and which passed through, the axis 232.

In this embodiment, the gain medium system 230 comprises a first part 230a and a second part 230b. Two turbines (or first pumps) are provided: a first turbine 244a (shown schematically as a grey ellipse) arranged to pump gain medium around the first part 230a of the gain medium system 230; and a second turbine 244b (shown schematically as a grey ellipse) arranged to pump gain medium around the second part 230b of the gain medium system 230. FIG. 11B shows an exploded view of the gain medium system 230 in which the first part 230a of the gain medium system 230 and the second part 230b of the gain medium system 230 have been separated in an axial direction for ease of understanding of the gas flows through the gain medium system 230.

The two turbines 244a, 244b are operable to pump gain medium from a central portion of the optical amplifier 200, radially outwards and through the eight second heat exchangers 228. The first turbine 244a is operable to pump gain medium from a central portion of the optical amplifier 200, radially outwards and through four of the second heat exchangers 228; and the second turbine 244b is operable to pump gain medium from a central portion of the optical amplifier 200, radially outwards and through the other four second heat exchangers 228. The flow of gain medium through the second heat exchangers 228 is indicated schematically in FIGS. 11A and 11B by dotted lines. The second heat exchangers 228 are arranged to transfer heat from the gain medium in the gain medium system 230 to a cooling fluid in the cooling system (not shown) after the gain medium has passed through the first pump 108 and before it has entered the amplification chambers of the sixteen tubes 210.

The gain medium from each of the second heat exchangers 228 then flows axially into one of the three corner modules 206 or the optical interface module 204 in which the flow is split and flows through two of the sixteen tubes 210 towards two of the side modules 208. The flow of gain medium through the tubes 210 is indicated schematically in FIGS. 11A and 11B by solid lines.

The flow from each pair of generally coaxial tubes 210 flows from both directions into one of the side modules 208, where these flows join and flow into one of the eight return modules 226. Through each of the return modules 226, the flow starts generally radially outwards and curves round until it is generally radially inwards and flows into one of the first heat exchangers 224. The flow of gain medium through the return modules 226 and the first heat exchangers 224 is indicated schematically in FIGS. 11A and 11B by dashed lines.

The gas mixture of the gain medium may be pumped, for example continuously, through the gain medium system 230. The gas mixture may comprise carbon dioxide, oxygen, carbon monoxide, nitrogen, hydrogen, xenon and/or helium.

As explained above, in embodiments of the present disclosure, a swirl inducer and a pair of electrodes are configured such that a pitch of the generally helical flow of fluid (gain medium) through the amplification chamber is generally matched to a pitch of the pair of electrodes along an amplification chamber. In some embodiments, this matching is sufficient so as to avoid, or at least limit, a pointing error developed during a start-up period of the optical amplifier 100, 100a, 200.

In some embodiments, an optical path of each of amplification chambers 110, 210 may be of the order of 0.5 m. In some embodiments, an optical path of the optical amplifier 100, 100a, 200 may be of the order of 8 m. In such embodiments it may be desirable for an offset from the optical axis caused during start-up is less than 0.04 mm. Over an optical path length of 8 m, an offset from the optical axis of 0.04 mm corresponds to an angular pointing error of 5 μrad.

In some embodiments, the swirl inducer 112 and the pair of electrodes 114, 116 are configured such that a matching of the pitch of the generally helical flow of fluid 126, 128 through the amplification chamber 110 to a pitch of the pair of electrodes 114, 116 along the amplification chamber 110 is such that an angular pointing error that results during a start-up period in which a temperature of the gain medium increases from a starting temperature up to a steady-state operating temperature the is less than 5 μrad.

Some embodiments of the present invention relate to a method of designing an apparatus for an optical amplifier 100, 100a, 200, wherein the optical amplifier 100, 100a, 200 comprises: an amplification chamber 110, 210; a swirl inducer 112; a pair of electrodes 114, 116; and a first pump 108, 244a, 244b. The amplification chamber 110, 210 is generally of the form of a tube and configured to receive the laser beam at an inlet and output an amplified laser beam from an outlet. The swirl inducer 112 is arranged to induce swirl in a fluid when pumped through the amplification chamber 110, 210 so as to induce a generally helical flow of fluid through the amplification chamber 110, 210. The pair of electrodes 114, 116 is arranged to apply a voltage within the amplification chamber 110, 210 and each of the pair of electrodes is generally helical. The first pump 108, 244a, 244b is configured to pump a gain medium around a gain medium system comprising the amplification chamber 110, 210. The new method comprises matching the swirl inducer 112 to the pair of electrodes 114, 116 such that a pitch of the generally helical flow of fluid through the amplification chamber 110 is generally matched to a pitch of the pair of electrodes 114, 116 along the amplification chamber 110.

Advantageously, the new method allows for the apparatus and/or the optical amplifiers described above with reference to FIGS. 3 to 11B to be designed.

Some embodiments of the present disclosure relate to an amplification system for use in a laser system, the system comprising: a plurality of optical amplifiers, at least one or each optical amplifier of the plurality of optical amplifiers comprising an optical amplifier 100, 100a, 200 generally of the form described above.

Some embodiments of the present disclosure relate to a laser system comprising: a laser configured to generate a laser beam; and an amplification system configured to amplify the laser beam.

Some embodiments of the present disclosure relate to a radiation system comprising: an EUV radiation source; and a laser system.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the clauses and claims set out below.

### CLAUSES

1. An apparatus for an optical amplifier configured to amplify a laser beam, the apparatus comprising:
   an amplification chamber, the amplification chamber being generally of the form of a tube;
   a swirl inducer arranged to induce swirl in a fluid when pumped through the amplification chamber so as to induce a generally helical flow of fluid through the amplification chamber; and
   a pair of electrodes arranged to apply a voltage within the amplification chamber, wherein each of the pair of electrodes is generally helical; wherein:
the swirl inducer and the pair of electrodes are configured such that a pitch of the generally helical flow of fluid through the amplification chamber is generally matched to a pitch of the pair of electrodes along the amplification chamber.
2. The apparatus of clause 1 wherein the each of the pair of electrodes is generally helical, having a pitch that increases from a first end of the amplification chamber to a second end of the amplification chamber.
3. An apparatus for an optical amplifier configured to amplify a laser beam, the apparatus comprising:
   an amplification chamber, the amplification chamber being generally of the form of a tube;
   a swirl inducer arranged to induce swirl in a fluid when pumped through the amplification chamber so as to induce a generally helical flow of fluid through the amplification chamber; and
   a pair of electrodes arranged to apply a voltage within the amplification chamber, wherein each of the pair of electrodes is generally helical, having a pitch that increases from a first end of the amplification chamber to a second end of the amplification chamber.
4. The apparatus of clause 2 or clause 3 wherein the swirl inducer is axially adjacent the first end of the amplification chamber.
5. The apparatus of any preceding clause wherein the swirl inducer is at least partially disposed in the amplification chamber.
6. An apparatus for an optical amplifier configured to amplify a laser beam, the apparatus comprising:
   an amplification chamber, the amplification chamber being generally of the form of a tube;
   a swirl inducer arranged to induce swirl in a fluid when pumped through the amplification chamber so as to induce a generally helical flow of fluid through the amplification chamber, wherein the swirl inducer is at least partially disposed in the amplification chamber; and
   a pair of electrodes arranged to apply a voltage within the amplification chamber, wherein each of the pair of electrodes is generally helical.
7. The apparatus of any preceding clause wherein the swirl inducer and the pair of electrodes are configured such that a chirality of the generally helical flow of fluid through the amplification chamber is the same as a chirality of the pair of electrodes along the amplification chamber.
8. The apparatus of any preceding clause wherein the amplification chamber is formed from quartz.
9. The apparatus of any preceding clause wherein the pair of electrodes are not disposed in an interior of the amplification chamber.
10. The apparatus of any preceding clause wherein the pair of electrodes are arranged to apply a voltage within the amplification chamber that is generally transverse or perpendicular to an axis of the amplification chamber.
11. The apparatus of any preceding clause wherein the swirl inducer comprises a generally tubular body and a screw structure disposed within the generally tubular body.
12. The apparatus of any preceding clause wherein the swirl inducer comprises a generally tubular body and plurality of baffles disposed within the generally tubular body, wherein each of the plurality of baffles extends generally radially and axially within the generally tubular body, and wherein each of the plurality of baffles is twisted such that a radial direction of the baffle varies along an axial extent of the baffle.
13. An optical amplifier configured to amplify a laser beam, the optical amplifier comprising:
   an apparatus according to any preceding clause, wherein the amplification chamber is configured to receive the laser beam at an inlet and output an amplified laser beam from an outlet; and a first pump configured to pump a gain medium around a gain medium system comprising the swirl inducer and the amplification chamber.
14. The optical amplifier of clause 13 comprising a plurality of apparatus according to any one of clauses 1 to 12, each amplification chamber being configured to receive the laser beam at an inlet and output an amplified laser beam from an outlet and wherein the first pump is configured to pump the gain medium around a gain medium system comprising the swirl inducers and the amplification chambers of the plurality of apparatus.
15. The optical amplifier of clause 13 or clause 14 wherein the swirl inducer and the pair of electrodes are configured such that a matching of the pitch of the generally helical flow of fluid through the amplification chamber to a pitch of the pair of electrodes along the amplification chamber is such that an angular pointing error that results during a start-up period in which a temperature of the gain medium increases from a starting temperature up to a steady-state operating temperature the is less than 10 μrad.
16. A method of designing an apparatus for an optical amplifier, the optical amplifier comprising:
   an amplification chamber, the amplification chamber being generally of the form of a tube and configured to receive the laser beam at an inlet and output an amplified laser beam from an outlet;
   a swirl inducer arranged to induce swirl in a fluid when pumped through the amplification chamber so as to induce a generally helical flow of fluid through the amplification chamber;
   a pair of electrodes arranged to apply a voltage within the amplification chamber, wherein each of the pair of electrodes is generally helical; and
   a first pump configured to pump a gain medium around a gain medium system comprising the amplification chamber; and
wherein the method comprises:
matching the swirl inducer to the pair of electrodes such that a pitch of the generally helical flow of fluid through the amplification chamber is generally matched to a pitch of the pair of electrodes along the amplification chamber.
17. An amplification system for use in a laser system, the system comprising:
   a plurality of optical amplifiers, at least one or each optical amplifier of the plurality of optical amplifier comprising an optical amplifier according to any one of clauses 13 to 15.
18. A laser system comprising:
   a laser configured to generate a laser beam; and
   the amplification system according to clause 17 wherein the amplification system is configured to amplify the laser beam.
19. A radiation system comprising:
   an EUV radiation source; and
   a laser system according to clause 18.
20. A lithographic system comprising a radiation system according to clause 19 and a lithographic apparatus.

1.-18. (canceled)

19. An apparatus for an optical amplifier configured to amplify a laser beam, the apparatus comprising:
an amplification chamber, the amplification chamber being generally of the form of a tube;
a swirl inducer arranged to induce swirl in a fluid when pumped through the amplification chamber so as to induce a generally helical flow of fluid through the amplification chamber; and
a pair of electrodes arranged to apply a voltage within the amplification chamber, wherein each of the pair of electrodes is generally helical,
wherein the swirl inducer and the pair of electrodes are configured such that a pitch of the generally helical flow of fluid through the amplification chamber is generally matched to a pitch of the pair of electrodes along the amplification chamber.

20. The apparatus of claim 19, wherein the each of the pair of electrodes is generally helical, having a pitch that increases from a first end of the amplification chamber to a second end of the amplification chamber.

21. An apparatus for an optical amplifier configured to amplify a laser beam, the apparatus comprising:
an amplification chamber, the amplification chamber being generally of the form of a tube;
a swirl inducer arranged to induce swirl in a fluid when pumped through the amplification chamber so as to induce a generally helical flow of fluid through the amplification chamber; and
a pair of electrodes arranged to apply a voltage within the amplification chamber, wherein each of the pair of electrodes is generally helical, having a pitch that increases from a first end of the amplification chamber to a second end of the amplification chamber.

22. The apparatus of claim 20, wherein the swirl inducer is axially adjacent the first end of the amplification chamber.

23. The apparatus of claim 19, wherein the swirl inducer is at least partially disposed in the amplification chamber.

24. An apparatus for an optical amplifier configured to amplify a laser beam, the apparatus comprising:
an amplification chamber, the amplification chamber being generally of the form of a tube;
a swirl inducer arranged to induce swirl in a fluid when pumped through the amplification chamber so as to induce a generally helical flow of fluid through the amplification chamber, wherein the swirl inducer is at least partially disposed in the amplification chamber; and
a pair of electrodes arranged to apply a voltage within the amplification chamber, wherein each of the pair of electrodes is generally helical.

25. The apparatus of claim 24, wherein the swirl inducer and the pair of electrodes are configured such that a chirality of the generally helical flow of fluid through the amplification chamber is the same as a chirality of the pair of electrodes along the amplification chamber.

26. The apparatus of claim 24, wherein the pair of electrodes are arranged to apply a voltage within the amplification chamber that is generally transverse or perpendicular to an axis of the amplification chamber.

27. The apparatus of claim 24, wherein the swirl inducer comprises a generally tubular body and a screw structure disposed within the generally tubular body.

28. The apparatus of claim 24, wherein the swirl inducer comprises a generally tubular body and plurality of baffles disposed within the generally tubular body, wherein each of the plurality of baffles extends generally radially and axially within the generally tubular body, and wherein each of the plurality of baffles is twisted such that a radial direction of the baffle varies along an axial extent of the baffle.

29. An optical amplifier configured to amplify a laser beam, the optical amplifier comprising:
an apparatus of claim 24, wherein the amplification chamber is configured to receive the laser beam at an inlet and output an amplified laser beam from an outlet; and
a first pump configured to pump a gain medium around a gain medium system comprising the swirl inducer and the amplification chamber.

30. The optical amplifier comprising a plurality of apparatus of claim 24, each amplification chamber being configured to receive the laser beam at an inlet and output an amplified laser beam from an outlet and wherein the first pump is configured to pump the gain medium around a gain medium system comprising the swirl inducers and the amplification chambers of the plurality of apparatus.

31. The optical amplifier of claim 29, wherein the swirl inducer and the pair of electrodes are configured such that a matching of the pitch of the generally helical flow of fluid through the amplification chamber to a pitch of the pair of electrodes along the amplification chamber is such that an angular pointing error that results during a start-up period in which a temperature of the gain medium increases from a starting temperature up to a steady-state operating temperature the is less than 10 μrad.

32. A method of designing an apparatus for an optical amplifier, the optical amplifier comprising an amplification chamber, the amplification chamber being generally of the form of a tube and configured to receive the laser beam at an inlet and output an amplified laser beam from an outlet, a swirl inducer arranged to induce swirl in a fluid when pumped through the amplification chamber so as to induce a generally helical flow of fluid through the amplification chamber, a pair of electrodes arranged to apply a voltage within the amplification chamber, wherein each of the pair of electrodes is generally helical, and a first pump configured to pump a gain medium around a gain medium system comprising the amplification chamber, wherein the method comprises:
matching the swirl inducer to the pair of electrodes such that a pitch of the generally helical flow of fluid through the amplification chamber is generally matched to a pitch of the pair of electrodes along the amplification chamber.

33. An amplification system for use in a laser system, the system comprising:
a plurality of optical amplifiers, at least one or each optical amplifier of the plurality of optical amplifier comprising an optical amplifier of claim 29.

34. A laser system comprising:
a laser configured to generate a laser beam; and
the amplification system of claim 33, wherein the amplification system is configured to amplify the laser beam.

35. A radiation system comprising:
an EUV radiation source; and
a laser system of claim 34.

36. A lithographic system comprising a radiation system of claim 35, and a lithographic apparatus.
